(19) United States
(12) Patent Application Publication
(10) Pub. No.: US 2020/0103687 A1
(43) Pub. Date: Apr. 2, 2020

(54) DISPLAY

(71) Applicant: AU Optronics Corporation, HSIN-CHU (TW)

(72) Inventor: Yi-Wen CHANG, HSIN-CHU (TW)

(21) Appl. No.: 16/542,804

(22) Filed: Aug. 16, 2019

(30) Foreign Application Priority Data
Sep. 28, 2018 (TW) 107134509

(51) Int. Cl. G02F 1/1347; G02F 1/1343; G02F 1/1335

(52) U.S. Cl. CPC G02F 1/1347; G02F 1/134309; G02F 1/133514; H01L 27/3232; G02F 2201/16; G02F 2201/121; G02F 2201/44; G02F 2201/123

(57) ABSTRACT

A display includes a display module, a shutter module, and a backlight module. The display module includes a first liquid crystal layer, first pixel electrodes, and a color filter layer. The first pixel electrodes and the color filter layer are located on opposite sides or on the same side of the first liquid crystal layer. The shutter module includes a second crystal layer, second pixel electrodes, and a common electrode layer. The second liquid crystal layer is interposed between the second pixel electrodes and the common electrode layer, and the shutter module is divided into dimming regions. The second pixel electrodes in each of the dimming regions are held at the same voltage. The backlight module provides light to the shutter module and the display module. The shutter module and the display module are located on the same side of the backlight module.

### RELATED APPLICATIONS

This application claims priority to Taiwan Application Serial Number 107134509, filed Sep. 28, 2018, which is herein incorporated by reference.

### BACKGROUND

### Field of Invention

The present disclosure relates to a display.

### Description of Related Art

A contrast ratio of current conventional display is limited by hardware itself, and is hard to have further breakthroughs, thus causing the contents of screen to be unrecognizable in certain scenarios due to the low contrast ratio. For example, in an environment of high brightness, the display may reflect external light and cause the overall image to be too bright. Furthermore, it is difficult to make further breakthroughs for the conventional hardware due to cost considerations, and thus the above problems is difficult to be solved.

### SUMMARY

An aspect of the present disclosure is to provide a display including a display module, a shutter module, and a backlight module. The display module includes a first liquid crystal layer, first pixel electrodes, and a color filter layer. The first pixel electrodes and the color filter layer are located on opposite sides or on the same side of the first liquid crystal layer. The shutter module includes a second crystal layer, second pixel electrodes, and a common electrode layer. The second liquid crystal layer is interposed between the second pixel electrodes and the common electrode layer, and the shutter module is divided into dimming regions. The second pixel electrodes in each of the dimming regions are held at the same voltage. The backlight module provides light to the shutter module and the display module. The shutter module and the display module are located on the same side of the backlight module.

Another aspect of the present disclosure is to provide a display including a display module, a shutter module, and a plurality of voltage lines. The display module includes a color structure layer. The shutter module is disposed on the display module. The shutter module includes a liquid crystal layer, pixel electrodes, and a common electrode layer. The liquid crystal layer is disposed between the pixel electrodes and the common electrode layer, and the shutter module is divided into triangular regions. All of the pixel electrodes in each of the triangular regions share at least one of the voltage lines.

In the aforementioned embodiments of the present disclosure, the shutter module is stacked on the display to solve a problem of light leakage in dark state. Furthermore, the number of wires required to fabricate the shutter module is reduced by combining the respective pixel regions in the shutter module as the dimming regions. Finally, by designing the dimming regions in different geometric shapes to be suitable for different display contents, the display quality of the display is enhanced.

### BRIEF DESCRIPTION OF THE DRAWINGS

The disclosure can be more fully understood by reading the following detailed description of the embodiments, with reference made to the accompanying drawings as follows:

FIG. 1 is a schematic top view of a display according to an embodiment of the present disclosure;

FIG. 2 is a schematic cross-sectional view of the display shown in FIG. 1;

FIG. 3 is a schematic electrical circuit diagram of a first pixel electrode layer shown in FIG. 2;

FIG. 4 is a schematic diagram of a pixel arrangement of a display module and a shutter module according to an embodiment of the present disclosure;

FIG. 5A is a schematic diagram of pixel regions included in each dimming region in a shutter module according to an embodiment of the present disclosure;

FIG. 5B is a schematic diagram of pixel regions included in each dimming region in a shutter module according to another embodiment of the present disclosure;

FIG. 5C is a schematic diagram of pixel regions included in each dimming region in a shutter module according to another embodiment of the present disclosure; and

FIG. 6 is a schematic diagram illustrating a display image shown on a display according to an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

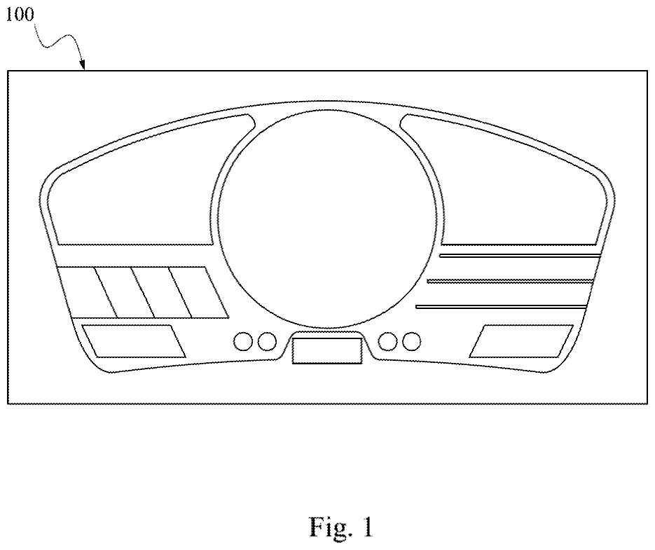

FIG. 1 is a schematic top view of a display 100 according to an embodiment of the present disclosure. As shown in FIG. 1, the display 100 can be placed in front of a driver's seat of a general automobile to display various driving related information such as time, vehicle speed, remaining oil amount, and interior temperature. Compared to conventional dial dashboards, the display 100 is more flexible in providing various information. Specifically, the display 100 in the present embodiment is a liquid crystal display (LCD), but in other embodiments, it is replaced with any display module having display functions. For example, the display module includes a color structure layer, and the color structure layer is a filter layer including a color filter, an organic light emitting layer including an organic light emitting diode (OLED), a light emitting layer including a light emitting diode (LED), or a combination thereof.

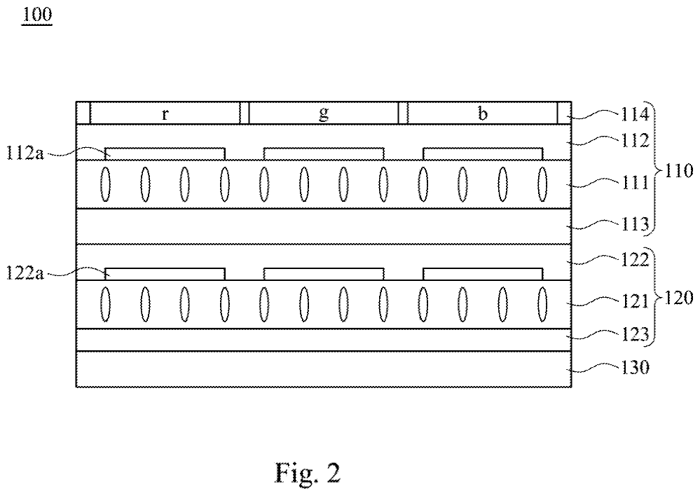

FIG. 2 is a schematic cross-sectional view of the display 100 shown in FIG. 1. As shown in FIG. 2, the display 100 mainly includes a display module 110, a shutter module 120, and a backlight module 130. The display module 110 includes a first liquid crystal layer 111, a first pixel electrode layer 112, a first common electrode layer 113, and a color filter layer 114. The first pixel electrode layer 112 and the color filter layer 114 are located on opposite sides of the first liquid crystal layer 111. The shutter module 120 includes a second crystal layer 121, a second pixel electrode layer 122, and a second common electrode layer 123. The second liquid crystal layer 121 is interposed between the second pixel electrode layer 122 and the second common electrode layer 123. The backlight module 130 provides light to the shutter module 120 and the display module 110, and the display module 110 and the shutter module 120 are located on the same side of the backlight module 130.

The stacked structure shown in FIG. 2 is merely illustrated as an example, and the present disclosure is not limited in this regard. For example, the display 100 also adopts a color filter on array (COA) structure. In this case, the first pixel electrode layer 112 and the color filter layer 114 are located on the same side of the first liquid crystal layer 111.

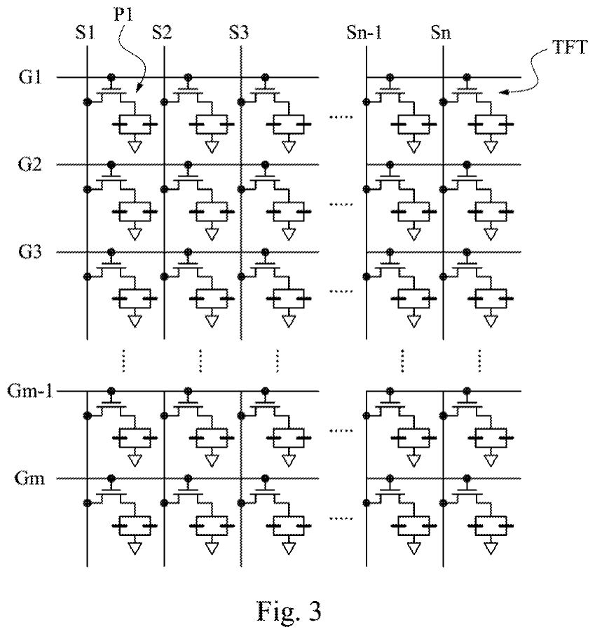

FIG. 3 is a schematic electrical circuit diagram of the first pixel electrode layer 112 shown in FIG. 2. As shown in FIG. 2 and FIG. 3, the first pixel electrode layer 112 includes first pixel electrodes 112a (not shown in FIG. 3), thin film transistors (TFTs), gate lines G1, G2, . . . , Gm, and source lines S1, S2, . . . , Sn. In the present embodiment, the gate lines and the source lines are disposed perpendicular to each other in a matrix. Each cell in the matrix is a pixel region P1 in which one of the first pixel electrodes 112a and one of the thin film transistors are disposed. The thin film transistors are electrically connected to the corresponding gate lines, source lines, and first pixel electrodes 112a. In the embodiment shown in FIG. 3, the gate lines and the source lines are straight lines and are substantially orthogonal to each other, but the present disclosure is not limited in this regard. For example, in another embodiment, the gate lines are designed as straight lines, and the source lines are designed as such as zigzag lines, such that the gate lines and the source lines intersect each other to form a plurality of parallelogrammatic or parallelogram-like pixel regions P1.

As shown in FIG. 2 and FIG. 3, when the gate line and the source line connected to one thin film transistors are simultaneously driven by voltage, an electric potential of the first pixel electrode 112a connected to the thin film transistor also changes, thus causing the liquid crystal molecules in the first liquid crystal layer 111 interposed between the first pixel electrode layer 112 and the first common electrode layer 113 to change their alignments, thereby changing the transmittance of the light emitted by the backlight module 130. Through the method mentioned above, it is possible to control a gray-scale value of each of the pixel regions P1.

In the present embodiment, the gray-scale value of each of the pixel regions P1 of the display module 110 has a total of 256 levels. Specifically, the display module 110 can control the transmittance of each of the pixel regions P1 by adjusting the electric potential of each of the first pixel electrodes 112a. In some embodiments, the average gray-scale value presented by each of the pixel regions P1 can be controlled by a light to dark time ratio of each of the first pixel electrodes 112a within a unit of time.

As shown in FIG. 2, the color filter layer 114 and the backlight module 130 are located on the opposite sides of the first liquid crystal layer 111. The color filter layer 114 includes filters of various colors, such as red (r), green (g), and blue (b) filters. In some embodiments, the color filter layer 114 includes red, green, blue, and white filters. In the present embodiment, each of the filters covers one pixel region P1, and thus the color filter layer 114 can convert the light passing through each of the pixel regions P1 into different colors. As a result, the display 100 can display a colorful image by a way of spatial color mixing.

The above paragraphs brief the technical method of using the display module 110 of the display 100 to display a colorful image. However, due to the characteristics of liquid crystals, a small portion of the light is allowed to pass through the liquid crystals when no voltage is applied, and thus the phenomenon of the light leakage in dark state of the display module 110 occurs. The light leakage in dark state reduces the contrast ratio of the image displayed, which causes the content to become unrecognizable in some scenarios. Taking the display 100 applied in a driving condition as an example, sunlight incidents directly on a cover glass of an uppermost layer of the display 100, and the light reflected by the cover glass further deteriorates the contrast ratio of the display image to an unrecognizable extent.

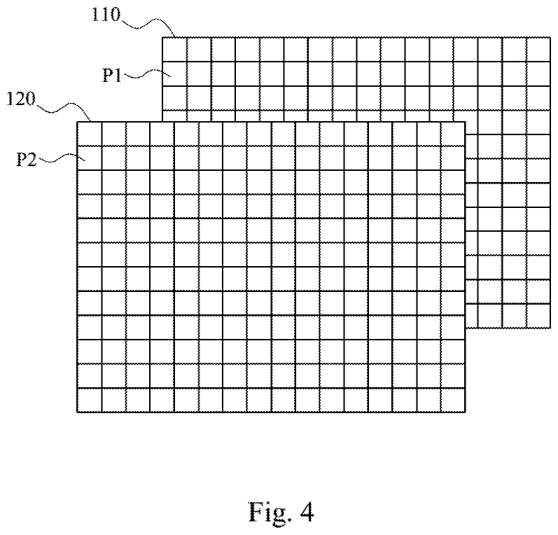

In the present embodiment, the shutter module 120 included in the display 100 can improve the aforementioned situation of the light leakage in dark state. As shown in FIG. 2, the second pixel electrode layer 122 of the shutter module 120 includes second pixel electrodes 122a, and each of the second pixel electrodes 122a corresponds to one pixel region P2 (referring to FIG. 4). The light transmittance of different pixel regions P1 in the shutter module 120 can be controlled by changing the voltage of the second pixel electrodes 122a, so as to further change the direction of the second liquid crystal layer 121. Furthermore, by adjusting the light transmittance of each of the pixel regions P2 in the shutter module 120, the light leakage in dark state of the display module 110 can be controlled, and the situation that the contrast ratio of the display 100 is reduced due to light leakage in dark state is improved.

FIG. 4 is a schematic diagram of a pixel arrangement of the display module 110 and the shutter module 120 according to an embodiment of the present disclosure. For details, as shown in FIG. 4, the display module 110 has pixel regions P1, and the shutter module 120 has pixel regions P2. In the present embodiment, the pixel regions P1 and the pixel regions P2 are rectangular and arranged in a matrix, and the pixel regions P1 and the pixel regions P2 are of the same size. In some embodiments, the pixel regions P1 and the pixel regions P2 of different shapes also are adopted. For example, the pixel regions P1 and the pixel regions P2 are designed as triangles, hexagons, or other polygons. In some embodiments, the sizes of the pixel regions P1 and the pixel regions P2 are different, and the pixel regions P1 and the pixel regions P2 are aligned or staggered with each other. In other words, pixel structures of the display module 110 and pixel structures of the shutter module 120 are independent of each other, and a designer makes adjustments according to the practical needs.

For example, the pixel structures of the shutter module 120 can be adjusted according to the scenarios of the display 100. Taking the present embodiment as an example, on the display 100 applied in a car driving state, the information is mainly displayed as texts and simple diagrams, in which the contrast ratio is more important than the resolution. Take manufacturing cost into account, the density of the pixel regions P2 in the shutter module 120 can be smaller than the density of the pixel regions P1 in the display module 110, and the light to dark contrast ratio of the display 100 can still be improved while a certain degree of sharpness is maintained.

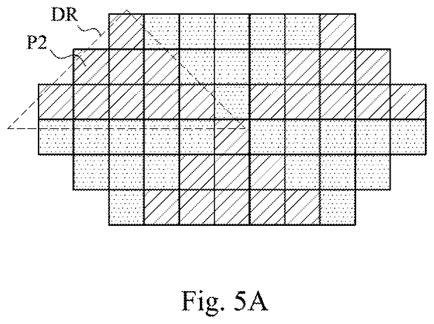

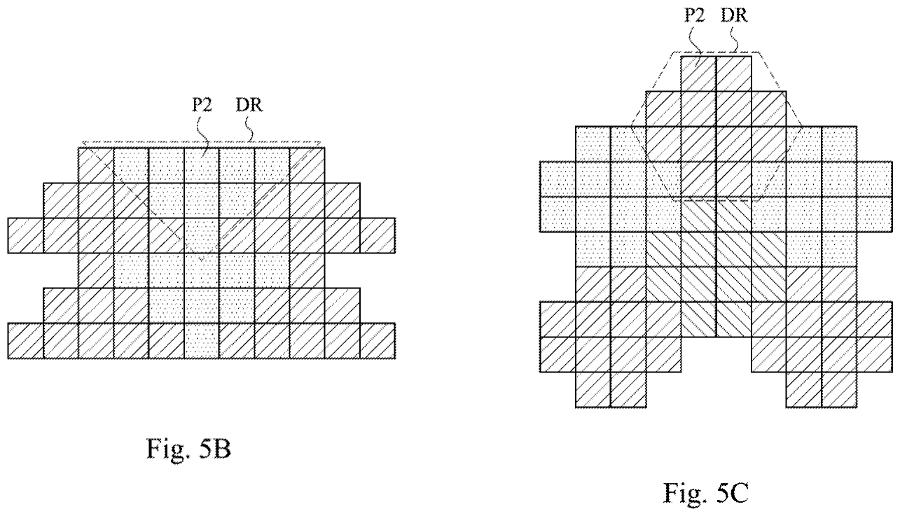

In the case in which the resolution requirement is lower, the pixel regions P2 in the shutter module 120 are further combined into one dimming region DR to serve as a basic pixel unit of the shutter module 120, so as to achieve the advantages of production cost. Specifically, referring to FIG. 5A, FIG. 5A is a schematic diagram of the pixel regions P2 included in each of the dimming regions DR in the shutter module 120 according to an embodiment of the present disclosure.

As shown in FIG. 5A, in some embodiments, the shutter module 120 is further divided into dimming regions DR, and the pixel regions P2 are included in each of the dimming regions DR. In the present embodiment, each of the dimming regions DR is approximately an isosceles triangle. Referring to FIG. 2 at the same time, it can be understood that a position of each of the dimming regions DR vertically projected onto the pixel regions P2 corresponds to one or more than one of the second pixel electrodes 122a. Furthermore, the second pixel electrodes 122a of all of the pixel regions P2 in the same dimming region DR are electrically connected to each other and are held at the same electric potential. If an external voltage is applied to one of the second pixel electrodes 122a in one dimming regions DR, all of the second pixel electrodes 122a in the dimming region DR will simultaneously change their electric potentials, and the light transmittance of the second liquid crystal layer 121 corresponding to the dimming region DR will also change. In other words, in such an embodiment, the minimum pixel unit of the shutter module 120 is the dimming region DR including the pixel regions P2 but not the pixel region P2 itself.

In the embodiment in which the dimming area DR is designed to be included, the number of the gate lines and the source lines is greatly reduced, and the fabrication cost of the corresponding control board is reduced. For example, in the embodiment shown in FIG. 5A, every nine of the pixel regions P2 are combined into one dimming region DR, and the dimming region DR only needs a corresponding gate line and a corresponding source line for control. In other words, the number of the gate lines and the source lines used is reduced to one-third of the original number thereof.

In some embodiments, the number of dimming regions DR is smaller, and each of the dimming regions DR can be electrically connected to one voltage line. Furthermore, the external control board can directly control the transmittance of each of the dimming regions DR by each of the voltage lines. In some cases, the resolution of the shutter module 120 only needs to reach one-fortieth of the resolution of the display module 110, and can still achieve the effects mentioned in the present disclosure. Taking the display module 110 with a resolution of 720*1280 as an example, the shutter module 120 includes 18*32 dimming regions DR, and only 576 voltage lines are needed in total, such that no problems on frame wiring are caused. By simply using the voltage lines to control the dimming regions DR, fabrication cost of the thin film transistor can be omitted, thus leading to significant advantages in manufacturing cost. In the present embodiment, the second common electrode layer 123 can also be fabricated as a voltage board, which further simplifies the manufacturing process.

As shown in FIG. 5A, in the present embodiment, the isosceles triangles are joined by vertex to vertex and bottom side to bottom side. That is to say, the bottom sides of the triangular dimming regions DR together form a straight line, and every six of the triangular dimming regions DR share one vertex.

In other embodiments, the isosceles triangles are joined in other ways. For example, FIG. 5B is another embodiment derived from that shown in FIG. 5A. As shown in FIG. 5B, the vertices of the triangular dimming regions DR are aligned with each other in line. In this case, every three of the triangular dimming regions DR share one vertex, and the vertex is located on a bottom side of another triangular dimming region DR. In other embodiments, the dimming regions DR is also approximately regular triangles, right triangles, or other triangles that can cover the entire plane of the shutter module 120.

In various embodiments, the dimensions of the triangles can be designed according to the practical needs. For example, if a length of one side of the isosceles triangle is L, lengths of the other two sides of the isosceles triangle may be between 0.85L and 1.15L.

FIG. 5C is a schematic diagram of the pixel regions P2 included in each of the dimming regions DR in the shutter module 120 according to another embodiment of the present disclosure. In the embodiment shown in FIG. 5C, each of the dimming regions DR is approximately a regular hexagon, and the regular hexagons are joined in a honeycombed manner to each other.

The shapes of different dimming regions DR are described above in FIG. 5A to FIG. 5C. As shown in FIG. 5A to FIG. 5C, the dimming regions DR includes only 10 to 12 pixel regions P2, and thus the shutter module 120 has a high resolution. However, the disclosure is not limited in this regard, and the size of each of the dimming regions DR can be adjusted according to the actual size of the display 100 and the resolution corresponding to the display module 110.

For example, in the aforementioned embodiment, the resolution of the shutter module 120 is one-fortieth of the resolution of the display module 110. That is to say, one dimming region DR can be combined by 40 pixel regions P2 in the shutter module 120. The dimming region DR formed by more pixel regions P2 ends up with a shape that is closer to a regular triangle, a regular quadrangle, a regular hexagon, or another geometric shape.

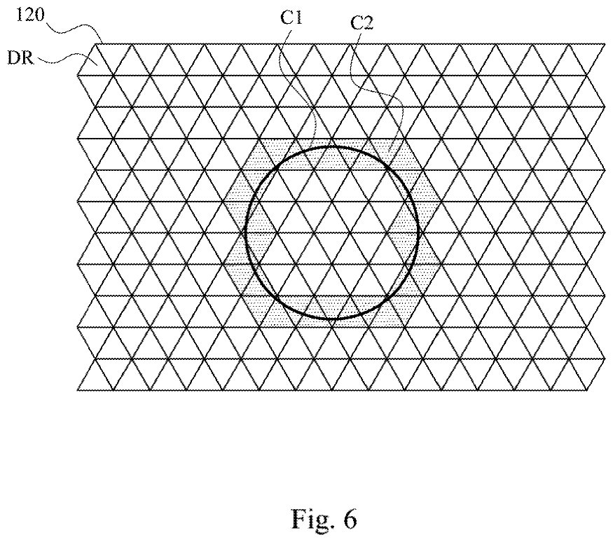

FIG. 6 is a schematic diagram illustrating a display image shown on the display 100 according to an embodiment of the present disclosure. As shown in FIG. 6, the display module 110 is omitted for the purpose of clarity, and only the corresponding relationship between the shutter module 120 and the image (circle image C1) displayed by the display module 110 is shown.

As shown in FIG. 6, the shutter module 120 includes dimming regions DR in shapes of regular triangles, and the light transmittance of dimming regions DR changes according to the image displayed by the display module 110. For example, the display module 110 displays a circle image C1 in FIG. 6, and the shutter module 120 increases the transmittance of the dimming region DR through which the circle image C1 passes, and a circle image C2 is generated on the shutter module 120. As shown in FIG. 6, since the resolution of the display module 110 is higher, the circular image C1 generated has a rather smooth profile. On the other hand, since the resolution of the shutter module 120 is lower, the circular image C2 generated has a partially zig-zag profile. In the present embodiment, the circle image C2 completely covers the circle image C1, such that the circle image C1 can be displayed by passing through the shutter module 120.

The dimming regions DR of different shapes are suitable for displaying images of different profiles. Therefore, the designer can equip the display 100 with the appropriate shutter module 120 according to an actual display content of the display module 110. Taking the embodiment shown in FIG. 6 as an example, the display 100 is equipped with a shutter module 120 including the dimming regions DR in shapes of regular triangles, in which the dimming regions DR in shapes of regular triangles can display the circle image C1 better. It is more suitable for this kind of the dimming regions DR to display figures with obliquely extending lines since the regular triangles are diagonally spliced on a plane. Similarly, by adopting the dimming regions DR in shapes of regular hexagons can also achieve the above described effects, and thus will not be described repeatedly herein.

In the embodiment shown in FIG. 6, the gray-scale value of each of the dimming regions DR has a total of two levels. That is to say, according to the image displayed by the display module 110, the light transmittance of each of the dimming regions DR is 100% or 0%. In some embodiments, the gray-scale value of the shutter module 120 can have more than two levels, thereby adjusting the contrast ratio of the image displayed by the display module 110. For example, if the gray-scale value has three levels, the light transmittance of each of the dimming regions DR is 100%, 50%, or 0%. As a result, in the embodiment shown in FIG. 6, the transmittance of each of the dimming regions DR is determined by a proportion occupied by the circle image C1 in each of the dimming regions DR. In this way, edges of the image displayed by the display module 110 can be made to have a gradation effect, which is visually softer.

In sum, the display in the present disclosure has the shutter module stacked on the display to solve a problem of the light leakage in dark state. Furthermore, the number of wires required to fabricate the shutter module is reduced by combining each of the pixel regions in the shutter module into the dimming regions. Moreover, by designing the dimming regions into different geometric shapes to suit different display contents, the display quality of the display is enhanced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A display, comprising:
a display module comprising a first liquid crystal layer, a plurality of first pixel electrodes, and a color filter layer, wherein the first pixel electrodes and the color filter layer are located on opposite sides or on a same side of the first liquid crystal layer;
a shutter module comprising a second crystal layer, a plurality of second pixel electrodes, and a common electrode layer, wherein the second liquid crystal layer is interposed between the second pixel electrodes and the common electrode layer, the shutter module is divided into a plurality of dimming regions, and the second pixel electrodes in each of the dimming regions are held at a same voltage; and
a backlight module configured to provide light to the shutter module and the display module, wherein the shutter module and the display module are located on a same side of the backlight module.

2. The display of claim 1, wherein each of the dimming regions is a triangle, and a length of one side of the triangle is L, and lengths of the other two sides of the triangle are from 0.85L to 1.15L, and the triangle is an isosceles triangle or a regular triangle.

3. The display of claim 2, wherein the dimming regions are arranged in rows, and bottom sides of the isosceles triangles in each of the rows collectively form a straight line.

4. The display of claim 3, wherein every six of the isosceles triangles share a vertex.

5. The display of claim 3, wherein every three of the isosceles triangles share a vertex, and the vertex is located on a bottom side of one of the isosceles triangles.

6. The display of claim 1, wherein the dimming regions are triangles, regular triangles, or regular hexagons.

7. The display of claim 1, further comprising a plurality of voltage lines, wherein all of the second pixel electrodes in each of the dimming regions share at least one of the voltage lines.

8. A display, comprising:
a display module comprising a color structure layer;
a shutter module disposed on the display module, wherein the shutter module comprises a liquid crystal layer, a plurality of pixel electrodes, and a common electrode layer, and the liquid crystal layer is disposed between the pixel electrodes and the common electrode layer, and the shutter module is divided into a plurality of triangular regions; and
a plurality of voltage lines, wherein all of the pixel electrodes in each of the triangular regions share at least one of the voltage lines.

9. The display of claim 8, wherein the triangular regions are isosceles triangles.

10. The display of claim 8, wherein each of the triangular regions corresponds to one or more than one of the pixel electrodes in a vertical projection direction.

11. The display of claim 8, wherein the color structure layer is a filter layer, an organic light emitting layer, a light emitting diode, or a combination thereof.
